(19) United States
(12) Patent Application Publication
(10) Pub. No.: US 2006/0176063 A1
(43) Pub. Date: Aug. 10, 2006

(54) Capacitive sensor

(76) Inventors: Hyeong-Joon Ahn, Seoul (KR); Dong-Chul Han, Seoul (KR)

Correspondence Address: CANTOR COLBURN, LLP, 55 GRIFFIN ROAD SOUTH, BLOOMFIELD, CT, 06002, US

(21) Appl. No.: 11/055,233

(22) Filed: Feb. 10, 2005

(51) Int. Cl. G01R 27/26

(52) U.S. Cl. 324/688

(57) ABSTRACT

A capacitive sensor for simultaneously sensing radial movement and axial movement of a rotary body. The capacitive sensor includes a sensor housing having a pocket disposed in a radial direction and provided with one side surface opened in an axial direction; a plurality of sensor electrodes inserted into the pocket; and an insulator inserted into the pocket to fill a space between the sensor housing and the sensor electrodes. Each of the sensor electrodes includes a radial sensor plane and an axial sensor plane, and the capacitive sensor further includes a guard formed between the sensor electrodes and the sensor housing.

### BACKGROUND OF THE INVENTION

1. Field of the Invention

The present invention relates to a capacitive sensor, and more particularly to a capacitive sensor for simultaneously sensing radial and axial movements of a rotating body.

2. Description of the Related Art

Generally, a five-axis active magnetic bearing rotor system (hereinafter, referred to as a ‘system’) requires four independent radial sensors and one axial sensor. In order to install the axial sensor in the above system, a sufficient axial space in an area for installing the axial sensor is necessary, thereby increasing the length of a rotor, thus decreasing a natural frequency of the system. Since a clearance of the area for installing the axial sensor significantly affects the system performance, the installation position of the axial sensor is an important parameter of the system design. Accordingly, it is necessary to properly design the system, in which the axial sensor is installed, thereby complicating the structure of the system.

The system generally uses probe-type displacement sensors. Since the displacement sensors measure only one point on a surface, the displacement sensors are very sensitive to surface quality or geometric errors of the measured surface, thus requiring additional treatment for compensating for the above errors. Accordingly, the current system uses cylindrical capacitive sensors with enlarged area, which are less sensitive to surface quality or geometric errors of the measured surface.

Since the conventional capacitive sensor serves only as a radial sensor, an axial sensor is additionally required, thereby complicating the structure of the system and increasing the axial length of the system, thus reducing a natural frequency of the system.

In order to simplify the structure of the system and improve dynamic characteristics of the system, the system uses a conical sensor serving as a radial sensor as well as an axial sensor. However, the conical sensor generates problems caused by the coupling of radial and axial movements of the system when the two movements of the system are measured, and it is difficult to install the conical sensor and perform a measuring operation using the conical sensor.

### SUMMARY OF THE INVENTION

Therefore, the present invention has been made in view of the above problems, and it is an object of the present invention to provide an improved capacitive sensor, which serves as a radial sensor as well as an axial sensor.

It is another object of the present invention to provide a capacitive sensor, which reduces the complexity of a system so that a system can be flexibly designed, and increases the dynamic characteristics of the system.

In accordance with the present invention, the above and other objects can be accomplished by the provision of a capacitive sensor comprising: a sensor housing having a pocket disposed in a radial direction and provided with one side surface opened in an axial direction; a plurality of sensor electrodes inserted into the pocket; and an insulator inserted into the pocket to fill a space between the sensor housing and the sensor electrodes.

Preferably, each of the sensor electrodes may include a radial sensor plane and an axial sensor plane, and the capacitive sensor may further comprise a guard formed between the sensor electrodes and the sensor housing.

The capacitive sensor of the present invention represents movements of the sensor planes of the sensor electrodes with respect to a rotor by means of variations in capacitances, thereby measuring variations in clearances between the sensor planes and the rotor.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view of a capacitive sensor in accordance with the present invention;

FIG. 2 is a development view of the capacitive sensor of FIG. 1;

FIG. 3 is a sectional view taken along the line A-A of FIG. 2;

FIG. 4 is a perspective view of a conventional capacitive sensor;

FIG. 5 is a development view of the capacitive sensor of FIG. 4;

FIG. 6 is a sectional view taken along the line B-B of FIG. 5;

FIG. 7 is a schematic view illustrating an active magnetic bearing rotor system provided with the capacitive sensor of the present invention; and

FIG. 8 is a schematic view illustrating an active magnetic bearing rotor system provided with conventional radial and axial sensors.

### DESCRIPTION OF THE PREFERRED EMBODIMENTS

Now, a preferred embodiment of the present invention will be described in detail with reference to the annexed drawings. Hereinafter, the relation and configuration between a capacitive sensor in accordance with the present invention and a system using the same will be described in detail.

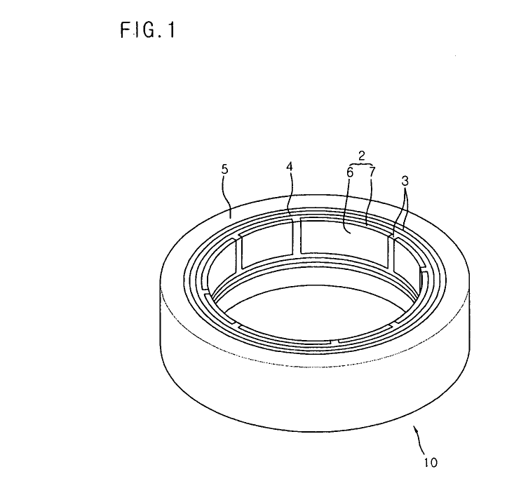

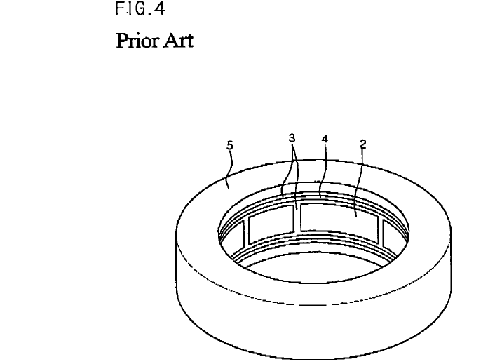

FIG. 1 is a perspective view of a capacitive sensor for simultaneously measuring radial and axial movements in accordance with the present invention, and FIG. 4 is a perspective view of a conventional capacitive sensor for measuring radial movement.

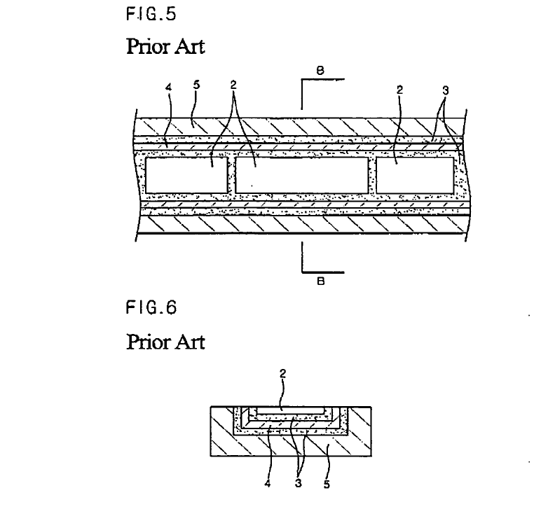

As shown in FIGS. 4 to 6, the conventional capacitive sensor comprises a sensor housing 5 having a radial pocket, a sensor electrode 2 having a plurality of radial sensor planes 6 inserted into the pocket, and an insulator 3 inserted into the pocket to fill a space between the sensor housing 5 and the sensor electrode 2.

Since the sensor electrode 2 is inserted into the pocket plane of the sensor housing 5, the conventional capacitive sensor can measure radial movement by measuring variation in capacitance according to variation in an interval between the radial sensor plane of the sensor electrode 2 and a rotor (not shown). However, since the sensor housing 5 surrounds the axial sensor plane of the sensor electrode 2, the conventional capacitive sensor cannot measure capacitance varied in the axial direction of the sensor electrode 2. Accordingly, the conventional capacitive sensor serves as only a radial sensor.

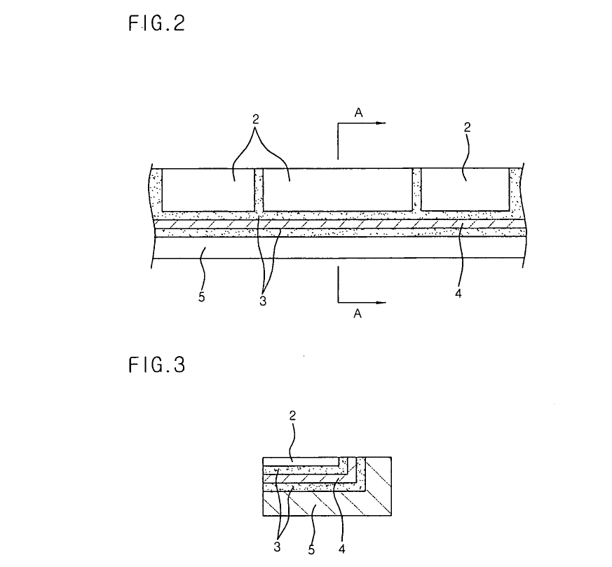

On the other hand, as shown in FIGS. 1 to 3, the capacitive sensor of the present invention comprises a sensor housing 5 having a radial pocket and provided with one side surface opened in the axial direction, a plurality of sensor electrodes 2 inserted into the pocket, and an insulator 3 inserted into the pocket to fill a space between the sensor housing 5 and the sensor electrodes 2.

Each of the sensor electrodes 2 includes a radial sensor plane 6 and an axial sensor plane 7. The capacitive sensor of the present invention further comprises a guard 4 formed between the sensor electrodes 2 and the sensor housing 5.

Since one radial side surface of the sensor housing 5 is opened, the capacitive sensor of the present invention, in the same manner as the conventional capacitive sensor, can measure radial movement by measuring variation in capacitance according to variations in gap between the radial sensor planes 6 of the sensor electrodes 2 and a rotor (not shown). Further, when axial movement of the rotor is generated, the capacitive sensor of the present invention can measure the axial movement by measuring variation in capacitance according to variations in gaps between the axial sensor planes 7 of the sensor electrodes 2 and the rotor.

The insulator 3 inserted into the space between the sensor electrodes 2 and the sensor housing 5 insulates the sensor electrodes 2 and the sensor housing 5 from each other.

In order to reduce effects of external disturbance, such as noise, on the capacitive sensor, the guard 4 is formed between the sensor electrodes 2 and the sensor housing 5.

By measuring the capacitances generated by the variations in the gap between the radial sensor planes 6 of the sensor electrodes 2 and the rotary shaft and between the axial sensor planes 7 of the sensor electrodes 2 and the rotor, the capacitance in the radial direction and the capacitance in the axial direction are measured. The capacitance of each of the sensor electrodes 2 are the sum of the capacitances of the corresponding sensor electrode 2 in the radial and the axial directions. The capacitance in the axial direction is calculated by the thickness and width of the sensor electrodes 2 and the gap between the sensor electrodes 2 and the rotor.

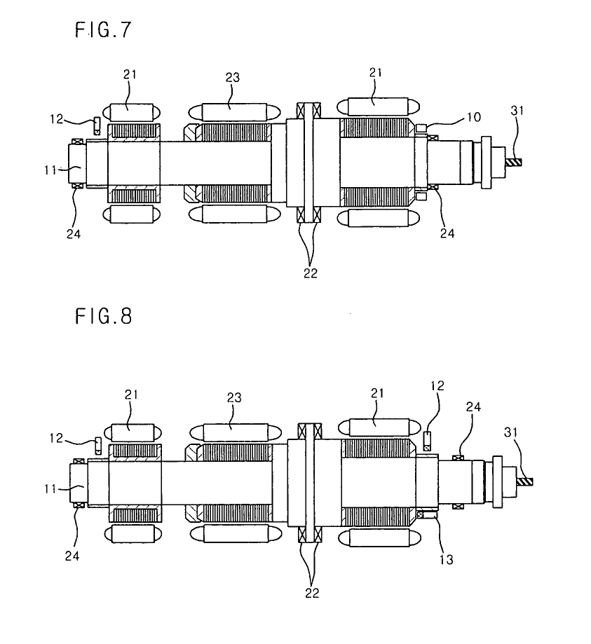

FIG. 8 is a schematic view illustrating an active magnetic bearing rotor system provided with conventional radial and axial sensors. FIG. 7 is a schematic view illustrating an active magnetic bearing rotor system provided with the capacitive sensor of the present invention serving as a radial sensor as well as an axial sensor.

Each of the above systems comprises a rotor 11, two backup bearings 24 for supporting the rotor 11 without levitation of active magnetic bearings, two active magnetic radial bearings 21 for supporting the rotor 11, and a pair of trust bearings 22 for supporting the rotor 11.

When the rotor 11, which is supported the active magnetic radial bearings 21, and the trust bearings 22, are rotated, the radial and axial movements of the rotor 11 are generated. The radial movement and the axial movement of the rotary shaft 11 are measured by radial sensors 12 and/or an axial sensor 13 installed at designated positions of the rotor 11 for sensing variations in clearances in the radial and axial directions.

When the measured values are inputted to a controller (not shown), the controller compares the measured values to reference values, and controls the current applied to the two active magnetic radial bearings 21 based on the obtained results, thereby controlling stiffness and damping force of the active magnetic radial bearings 21, thus improving stability and dynamic characteristics of the system.

The configuration and operation of the controller, which receives measured values of variations of clearances from the capacitances obtained by the radial and axial sensors 12 and 13 and controls the current applied to the active magnetic radial bearings 21 of the system based on the received values, are well known to those skilled in the art, and a detailed description thereof will thus be omitted because it is considered to be unnecessary.

In order to measure variations in clearances in the radial and axial directions of the system, the conventional system shown in FIG. 8 uses two radial sensors 12 and one axial sensor 13, but the system shown in FIG. 7 uses one radial sensor 12 and one capacitive sensor 10 of the present invention, serving as one radial sensor as well as one axial sensor.

The system of FIG. 7, which does not require any additional axial sensor, prevents increase in the length of the rotor for installing the axial sensor, thereby increasing a natural frequency of the system compared to the conventional system of FIG. 8. Further, the system of FIG. 7 reduces the number of the sensors to be installed therein, thereby eliminating the complexity of the system caused due to the installation of the sensors.

When one radial sensor 12 installed on one side of the system opposite to the capacitive sensor 10 is replaced with the capacitive sensor 10 serving as the radial sensor as well as the axial sensor, it is possible to measure the increase in the length of the rotor as well as the variations in clearances in the radial and axial directions of the rotor without an additional axial sensor.

As apparent from the above description, the present invention provides a capacitive sensor, which can simultaneously measure clearance variation in the radial and the axial directions.

The capacitive sensor of the present invention flexibly designs a sensor-installing portion when a system is designed, thereby simplifying the system. Further, the capacitive sensor increases a natural frequency of the system by reducing the longitudinal length of a rotary shaft due to the sensor-installing portion, thereby improving the stability and dynamic performance of the system.

In the case that both sensors of the system are replaced with the capacitive sensors of the present invention, it is possible to measure increase the longitudinal length of the rotor without an additional axial sensor.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1. A capacitive sensor comprising:
a sensor housing having a pocket disposed in a radial direction and provided with one side surface opened in an axial direction;
a plurality of sensor electrodes having sensor planes inserted into the pocket; and
an insulator inserted into the pocket to be filled in a space between the sensor housing and the sensor electrodes,
wherein each of the sensor electrodes is formed with an axial sensor plane and a radial sensor plane perpendicular to the axial sensor plane.

2. The capacitive sensor as set forth in claim 1,
wherein each of the sensor electrodes includes a radial sensor plane and an axial sensor plane.

3. (canceled)

4. The capacitive sensor as set forth in claim 2, further comprising a guard formed between the sensor electrodes and the sensor housing.
